(19) United States
(12) Patent Application Publication
(10) Pub. No.: US 2015/0316968 A1
(43) Pub. Date: Nov. 5, 2015

(54) POWER SUPPLY

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: YONG-CHANG FAN, Wuhan (CN); SAN-YONG YANG, Wuhan (CN)

(21) Appl. No.: 14/596,383

(22) Filed: Jan. 14, 2015

(30) Foreign Application Priority Data
Apr. 30, 2014 (CN) 201410180032.4

(51) Int. Cl. G06F 1/26; H02M 7/02; H02M 3/02; H05K 1/18

(52) U.S. Cl. CPC G06F 1/26; H05K 1/18; H02M 7/02; H02M 3/02

(57) ABSTRACT

A power supply includes a circuit board, a cable assembly, a voltage conversion component, and a DC voltage conversion component. The circuit board includes a connector. The cable assembly, the voltage conversion component, and the DC voltage conversion component are electrically connected to the circuit board. The cable assembly includes an external connector configured to connect to a peripheral circuit. The voltage conversion component can convert an AC voltage to a first DC voltage. The DC voltage conversion component can convert the first DC voltage to a second DC voltage. The power supply further includes a DC voltage conversion card to convert the second DC voltage to a third DC voltage. The cable assembly outputs the third DC voltage when the DC voltage conversion card is engaged with the connector, and the cable assembly outputs the second DC voltage when the DC voltage conversion card is disengaged from the connector.

### CROSS-REFERENCE TO RELATED APPLICATIONS

This application claims priority to Chinese Patent Application No. 201410180032.4 filed on Apr. 30, 2014, the contents of which are hereby incorporated by reference.

### FIELD

The subject matter herein generally relates to a power supply, and more particularly to a power supply which can be applied for different types of computers.

### BACKGROUND

Computers are generally classified into a commercial computer and a consumer computer. There are different input voltages between the two types of computers.

### BRIEF DESCRIPTION OF THE DRAWINGS

Implementations of the present technology will now be described, by way of example only, with reference to the attached figures.

FIG. 1 is an exploded, isometric view of a power supply in accordance with an embodiment.

FIG. 2 is similar to FIG. 1, but viewed from a different angle.

FIG. 3 is a partially assembled, isometric view of the power supply of FIG. 1.

FIG. 4 is an assembled, isometric view of the power supply of FIG. 1.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

The present disclosure is described in relation to a power supply including a circuit board, a cable assembly, a voltage conversion component, and a DC voltage conversion component. The circuit board includes a connector. The cable assembly, the voltage conversion component, and the DC voltage conversion component are electrically connected to the circuit board. The cable assembly includes an external connector configured to connect to a peripheral circuit. The voltage conversion component can convert an AC voltage to a first DC voltage. The DC voltage conversion component can convert the first DC voltage to a second DC voltage. The power supply further includes a DC voltage conversion card to convert the second DC voltage to a third DC voltage. The cable assembly outputs the third DC voltage when the DC voltage conversion card is engaged with the connector, and the cable assembly outputs the second DC voltage when the DC voltage conversion card is disengaged from the connector.

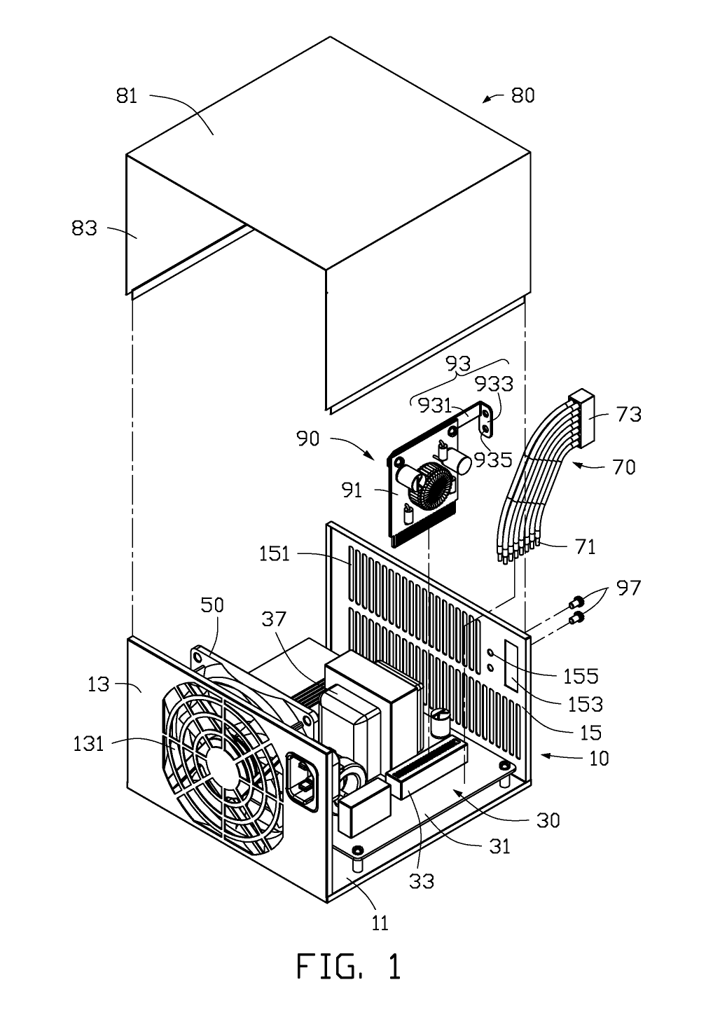

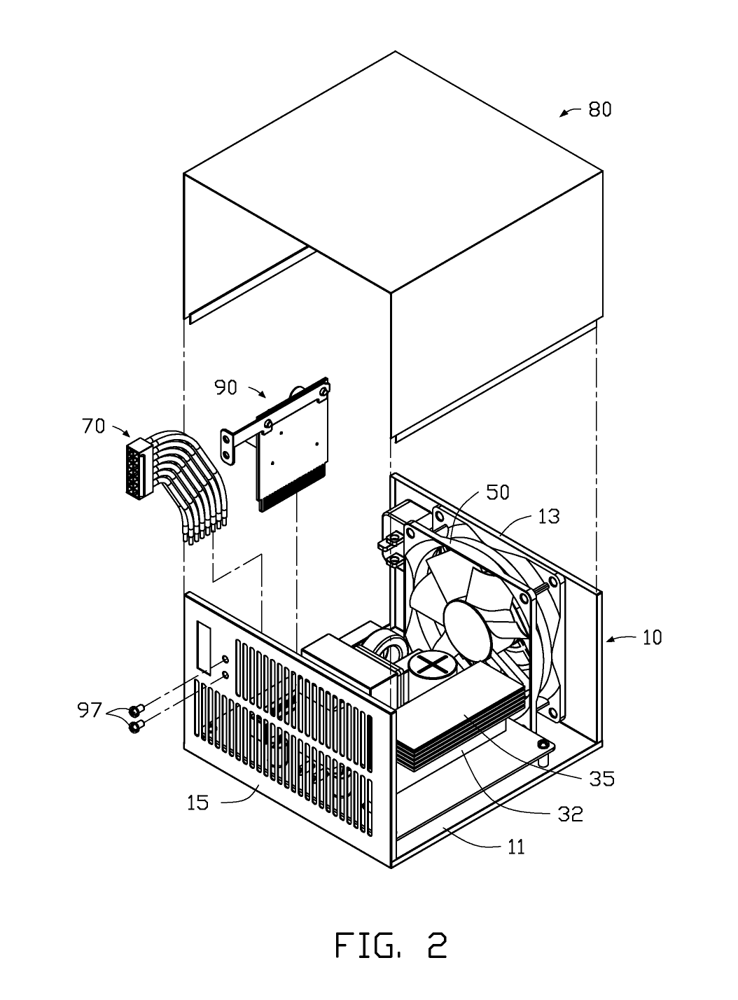

FIGS. 1 and 2 illustrate a power supply including an enclosure 10, a circuit board 30, a fan 50, a cable assembly 70, a cover 80, and a DC voltage conversion card 90.

The enclosure 10 includes a bottom plate 11, a front plate 13, and a rear plate 15 substantially parallel to the front plate 13. The front plate 13 and the rear plate 15 extend from two opposite sides of the bottom plate 11. The front plate 13 defines an air inlet 131. The fan 50 is mounted on an inner side of the front plate 13 and aligned with the air inlet 131. The rear plate 15 defines a plurality of vent holes 151, a mounting opening 153 and two mounting holes 155.

The circuit board 30 is mounted on the bottom plate 11. The circuit board 30 includes a main body 31 and a connector 33 electrically connected to the main body 31. The circuit board 30 further includes a voltage conversion component 32 mounted to the main body 31, a heat sink 35 attached to the voltage conversion component 32, and a DC voltage conversion component 37 mounted to the main body 31. The cable assembly 70 includes a cable 71 and an external connector 73 connected to the cable 71. The voltage conversion component 32 is configured to convert an AC voltage to a first DC voltage. The DC voltage conversion component 37 is configured to convert the first DC voltage output from the voltage conversion component 32 to a second DC voltage.

The DC voltage conversion card 90 includes a card body 91 and a mounting member 93 mounted to the card body 91. The mounting member 93 includes a mounting portion 931 mounted on the card body 91 and a clamping portion 933 perpendicularly extending from the mounting portion 931. The clamping portion 933 defines two clamping holes 935 corresponding to the mounting holes 155.

The cover 80 includes a top plate 81 and two sidewalls 83 perpendicularly extending from two opposite sides of the top plate 81.

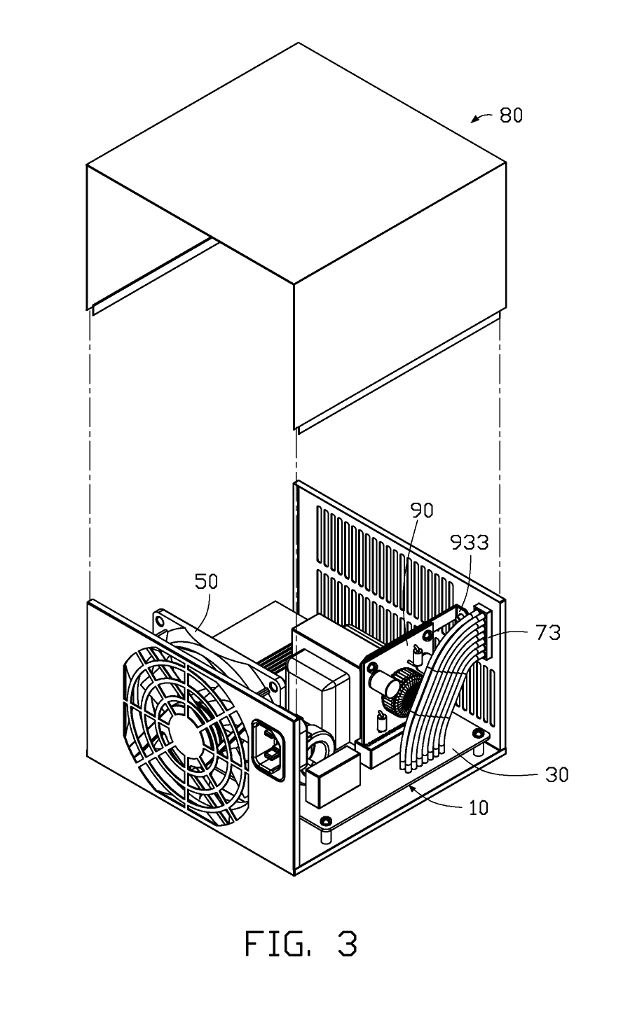

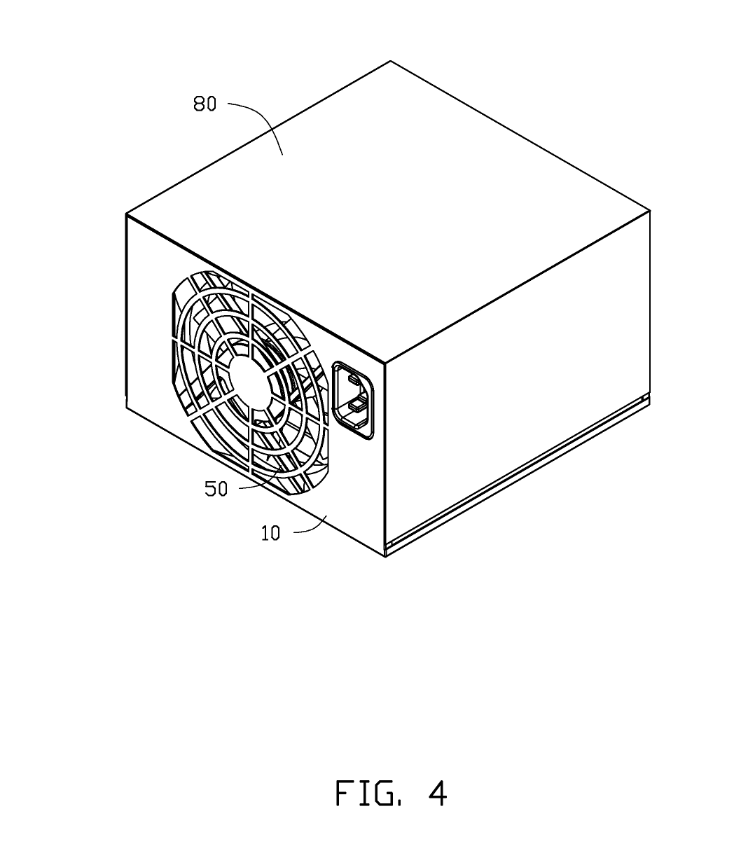

FIGS. 3 and 4 illustrate an assembly of the power supply. The card body 91 of the DC voltage conversion card 90 is engaged in the connector 33, and the clamping holes 935 are aligned with the mounting holes 155. The card body 91 is substantially perpendicular to the main body 31. The DC voltage conversion card 90 is configured to convert the second DC voltage output from the DC voltage conversion component 37 to a third DC voltage; and value of the third DC voltage is different from that of the second DC voltage.

Two fasteners 97 are inserted into the mounting holes 155 and the clamping holes 935 to mount the DC voltage conversion card 90 in the enclosure 10. An end of the cable 71 away from the external connector 73 is electrically connected to the main body 31 of the circuit board 30, and the external connector 73 is mounted in the mounting opening 153 and is configured to connect to a peripheral circuit. The cable assembly 70 can output the third DC voltage to the peripheral circuit when the card body 91 is engaged with the connector 33. The cable assembly 70 can only output the second DC voltage to the peripheral circuit when the card body 91 is disengaged from the connector 33.

The cover 80 is assembled to the enclosure 10 to form a closed space, in which the circuit board 30, the fan 50, the cable assembly 70, and the DC voltage conversion card 90 are received.

The embodiments shown and described above are only examples. Many details are often found in the art such as the other features of a power supply. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A power supply comprising:
an enclosure; and
a circuit board mounted in the enclosure, comprising:
a main body;
a voltage conversion component mounted to the main body and configured to convert an AC voltage to a first DC voltage;
a DC voltage conversion component configured to convert the first DC voltage to a second DC voltage; and
a connector mounted on the main body;
a DC voltage conversion card engaged with the connector and configured to convert the second DC voltage to a third DC voltage; and
a cable assembly mounted to the main body and configured to output the second DC voltage or the third DC Voltage to a peripheral circuit.

2. The power supply of claim 1, wherein the enclosure comprises a bottom plate and a rear plate extending from the bottom plate, the circuit board is mounted on the bottom plate, and the cable assembly comprises an external connector mounted to the rear plate and configured to connect to the peripheral circuit.

3. The power supply of claim 2, wherein the rear plate defines a mounting opening, and the external connector is mounted in the mounting opening.

4. The power supply of claim 2, wherein the rear plate is substantially perpendicular to the bottom plate.

5. The power supply of claim 2, wherein the DC voltage conversion card comprises a card body and a mounting member mounted to the card body, the card body is engaged with the connector, and the mounting member is mounted on the rear plate.

6. The power supply of claim 5, wherein the mounting member comprises a mounting portion mounted on the card body and a clamping portion extending from the mounting portion, the clamping portion defines a clamping hole, and the rear plate defines a mounting hole corresponding to the clamping hole.

7. The power supply of claim 5, wherein the card body is substantially perpendicular to the main body.

8. The power supply of claim 1, further comprising a cover, wherein the circuit board, the cable assembly, and the DC voltage conversion card are received in a closed space defined between the cover and the enclosure.

9. The power supply of claim 8, wherein the cover comprises a top plate and two sidewalls extending from the top plate.

10. The power supply of claim 2, wherein the rear plate defines a vent hole.

11. A power supply comprising:
a circuit board comprising a connector;
a cable assembly electrically connected to the circuit board;
a voltage conversion component electrically connected to the circuit board and being configured to convert an AC voltage to a first DC voltage;
a DC voltage conversion component electrically connected to circuit board and being configured to convert the first DC voltage to a second DC voltage; and
a DC voltage conversion card configured to convert the second DC voltage to a third DC voltage;
wherein the cable assembly outputs the third DC voltage when the DC voltage conversion card is engaged with the connector, and the cable assembly outputs the second DC voltage when the DC voltage conversion card is disengaged from the connector.

12. The power supply of claim 11, further comprising an enclosure, wherein the enclosure comprises a bottom plate and a rear plate extending from the bottom plate, the circuit board is mounted on the bottom plate, and the cable assembly comprises an external connector mounted to the rear plate and configured to connect to a peripheral circuit.

13. The power supply of claim 12, wherein the DC voltage conversion card comprises a card body and a mounting member mounted to the card body, and the card body is configured to be engaged with the connector.

14. The power supply of claim 12, wherein the rear plate defines a mounting opening, the external connector is mounted in the mounting opening.

15. The power supply of claim 12, wherein the rear plate is substantially perpendicular to the bottom plate.

16. The power supply of claim 13, wherein the mounting member comprises a mounting portion mounted on the card body and a clamping portion extending from the mounting portion, the clamping portion defines a clamping hole, and the rear plate defines a mounting hole corresponding to the clamping hole.

17. The power supply of claim 13, wherein the card body is substantially perpendicular to the circuit board.
